(19) United States
(12) Patent Application Publication
(10) Pub. No.: US 2025/0338721 A1
(43) Pub. Date: Oct. 30, 2025

(54) DISPLAY PANEL AND ELECTRONIC DEVICE

(71) Applicant: HKC CORPORATION LIMITED, SHENZHEN (CN)

(72) Inventors: Yangling TANG, SHENZHEN (CN); Qin LIANG, SHENZHEN (CN); Xiufeng ZHOU, SHENZHEN (CN); Zhisheng XIE, SHENZHEN (CN); Haijiang YUAN, SHENZHEN (CN)

(73) Assignee: HKC CORPORATION LIMITED, SHENZHEN (CN)

(21) Appl. No.: 19/068,041

(22) Filed: Mar. 3, 2025

(30) Foreign Application Priority Data
Apr. 29, 2024 (CN) 202410552033.0

(51) Int. Cl. H10K 59/122; H10K 59/35

(52) U.S. Cl. CPC H10K 59/122; H10K 59/353

(57) ABSTRACT

A display panel and an electronic device. The display panel includes multiple light-transmitting region columns, a conductive barrier structure, and a pixel unit group. The multiple light-transmitting region columns are arranged side by side and spaced apart in a first direction, and each light-transmitting region column includes multiple light-transmitting sub-regions spaced apart in a second direction. The conductive barrier structure surrounds to form multiple first pixel holding regions and multiple second pixel holding regions. The first pixel holding regions and the light-transmitting region columns are arranged side by side and staggered in the first direction. Each second pixel holding region is disposed at an interval between corresponding adjacent two light-transmitting sub-regions of a corresponding light-transmitting region column. The pixel unit group includes multiple pixel columns and first pixel units. The multiple pixel columns are arranged in the first pixel holding regions in a one-to-one correspondence.

### CROSS REFERENCE

The present disclosure claims priority of Chinese Patent Application No. 202410552033.0, filed on Apr. 29, 2024, the entire contents of which are hereby incorporated by reference in their entirety.

### TECHNICAL FIELD

The present disclosure relates to the field of display technologies, and more specifically to a display panel and electronic device.

### BACKGROUND

With the continuous development of display technology, organic light-emitting diode (OLED) has become a research hotspot and the direction of technological development for major manufacturers due to its advantages of wide color gamut, high contrast, thin and light design, self-luminous, and wide viewing angle, etc.

Nowadays, in order to meet user needs, some OLED display devices are required to have high light transmittance in a local functional region while displaying images normally, that is, a light-transmitting region is required to be arranged in the screen region above the light-sensing device (mainly the region of an under-screen camera). However, in existing display panels, the non-light-transmitting regions between the light-transmitting regions are not fully utilized, resulting in poor functional characteristics of the display panels.

### SUMMARY OF THE DISCLOSURE

The main object of the present disclosure is to provide a display panel and an electronic device intended to solve the technical problem of underutilizing the non-light-transmitting region between light-transmitting regions existing in the related art.

To solve the above technical problem, the present disclosure provides a display panel, including: a plurality of light-transmitting region columns, arranged side by side and spaced apart in a first direction; wherein each light-transmitting region column includes a plurality of light-transmitting sub-regions spaced apart in a second direction; the plurality of light-transmitting sub-regions of each adjacent two of the plurality of light-transmitting region columns are misaligned in the first direction, where the first direction is perpendicular to the second direction; a conductive barrier structure, surrounding to form a plurality of first pixel holding regions and a plurality of second pixel holding regions; wherein the plurality of first pixel holding regions and the plurality of light-transmitting region columns are arranged side by side and staggered in the first direction; each first pixel holding region includes a plurality of sub-holding regions connected to each other along the second direction, and each sub-holding region faces a corresponding light-transmitting sub-region; each second pixel holding region is disposed in an interval between corresponding adjacent two of the plurality of light-transmitting sub-regions of a corresponding light-transmitting region column; and a pixel unit group, including a plurality of pixel columns and a plurality of first pixel units; wherein the plurality of pixel columns are arranged in the plurality of first pixel holding regions in a one-to-one correspondence, and each pixel column extends along an extension direction of a corresponding first pixel holding region; the plurality of first pixel units are arranged in the plurality of second pixel holding regions in a one-to-one correspondence.

In some embodiments, each sub-holding region includes a first holding segment, a second holding segment, and a third holding segment; the first holding segment is connected to the second holding segment and the third holding segment; the first holding segment extends in the second direction; the second holding segment and the third holding segment are each extended in a direction inclined to the second direction; the first holding segment of one of the plurality of sub-holding regions is connected to the third holding segment of another of the plurality of sub-holding regions.

In some embodiments, the conductive barrier structure includes at least one first barrier structure and a plurality of second barrier structures; each first barrier structure is configured to form a corresponding first pixel holding region; each second barrier structure includes two barrier walls spaced apart in the second direction, and each of the two barrier walls is connected to a portion of the at least one first barrier structure to form a corresponding first pixel holding region, so as to form a corresponding second pixel holding region.

In some embodiments, each first pixel unit is a green pixel; two of the plurality of first pixel units located on both sides of each light-transmitting sub-region in the first direction are symmetrically arranged with respect to the light-transmitting sub-region; and/or, two of the plurality of first pixel units located on both sides of each light-transmitting sub-region in the second direction are symmetrically arranged with respect to the light-transmitting sub-region.

In some embodiments, in the first direction, one of each adjacent two of the plurality of pixel columns is a blue pixel column and the other is a red pixel column.

In some embodiments, each first pixel unit includes at least two first subpixels arranged in an extension direction of the first pixel unit, and each adjacent two of the at least two first subpixels are spaced apart by a pixel definition layer.

In some embodiments, each pixel column includes a plurality of second pixel units; each second pixel unit is disposed in a corresponding sub-holding region, and each adjacent two of the plurality of second pixel units are separated by a pixel definition layer.

In some embodiments, each second pixel unit includes at least two second subpixels arranged in an extension direction of the second pixel unit, and each adjacent two of the at least two second subpixels are spaced apart by the pixel definition layer.

In some embodiments, each light-transmitting sub-region is circular;
each light-transmitting sub-region is surrounded by two corresponding sub-holding regions and two corresponding adjacent second pixel holding regions.

To solve the above technical problem, the present disclosure further provides an electronic device, including a housing and the display panel as above.

The display panel includes multiple light-transmitting region columns, a conductive barrier structure, and a pixel unit group. The multiple light-transmitting region columns are arranged side by side and spaced apart in a first direction, and each light-transmitting region column includes multiple light-transmitting sub-regions spaced apart in a second direction. The light-transmitting sub-regions of two adjacent light-transmitting region columns are misaligned in the first direction, where the first direction is perpendicular to the second direction. The conductive barrier structure surrounds to form multiple first pixel holding regions and multiple second pixel holding regions. The first pixel holding regions and the light-transmitting region columns are arranged side by side and staggered in the first direction. Each first pixel holding region includes multiple sub-holding regions connected to each other along the second direction, and each sub-holding region faces a corresponding light-transmitting sub-region. Each second pixel holding region is disposed at an interval between corresponding adjacent two light-transmitting sub-regions of a corresponding light-transmitting region column. The pixel unit group includes multiple pixel columns and first pixel units. The multiple pixel columns are arranged in the first pixel holding regions in a one-to-one correspondence, and each pixel column extends along an extension direction of its corresponding first pixel holding region. The multiple first pixel units are arranged in the second pixel holding regions in a one-to-one correspondence. That is, the first pixel holding regions and the light-transmitting region columns are arranged side by side and staggered in the first direction, and there is a second pixel holding region in the interval between two adjacent light-transmitting sub-regions of each light-transmitting region column, such that the first pixel holding regions and the second pixel holding regions occupy as much as possible the non-light-transmitting region between the light-transmitting sub-regions. When the pixel column is arranged in the first pixel holding region and the first pixel unit is arranged in the second pixel holding region, the pixel column and the first pixel unit can be arranged in the gap between the light-transmitting sub-regions, making full use of the non-light-transmitting region between the light-transmitting regions, thereby increasing the pixel arrangement area of the display panel and increasing the pixel opening ratio, etc.

### BRIEF DESCRIPTION OF THE DRAWINGS

In order to more clearly illustrate the technical solutions in the embodiments of the present disclosure, the accompanying drawings to be used in the description of the embodiments will be briefly introduced below, and it will be obvious that the accompanying drawings in the following description are only some of the embodiments of the present disclosure, and other accompanying drawings can be obtained according to these drawings for the those skilled in the art, without any creative labor.

FIG. 1 is a first schematic structural view of a display panel according to some embodiments of the present disclosure.

FIG. 2 is a second schematic structural view of a display panel according to some embodiments of the present disclosure.

FIG. 3 is an enlarged schematic view of the structure within the broken-line frame in FIG. 2.

FIG. 4 is a partial cross-sectional structural view of the display panel shown in FIG. 2 along the A-A direction.

FIG. 5 is a third schematic structural view of a display panel according to some embodiments of the present disclosure.

FIG. 6 is a fourth schematic structural view of a display panel according to some embodiments of the present disclosure.

FIG. 7 is a partial cross-sectional structural view of the display panel shown in FIG. 6 along the B-B direction.

FIG. 8 is a schematic structural view of an electronic device according to some embodiments of the present disclosure.

### REFERENCE NUMERALS

electronic device 1; housing 20; display panel 10; light-transmitting region column 100; light-transmitting sub-region 110; conductive barrier structure 200; first pixel holding region 210; sub-holding region 211; first holding segment 2111; second holding segment 2112; third holding segment 2113; second pixel holding region 220; first barrier structure 230; second barrier structure 240; barrier wall 241; pixel unit group 300; pixel column 310; second pixel unit 311; second subpixel 3111; first pixel unit 320; first subpixel 321; pixel definition layer 400; first direction X; second direction Y.

### DETAILED DESCRIPTION

The following will describe in detail the embodiment of the technical solution of the present disclosure in conjunction with the drawings. The following embodiments are only intended to more clearly illustrate the technical solution of the present disclosure, and therefore serve only as examples, and cannot be regarded to limit the scope of the present disclosure.

Unless otherwise defined, all technical and scientific terms used herein shall have the same meaning as commonly understood by those skilled in the art. The terms used herein are for the purpose of describing specific embodiments only and are not intended to limit the present disclosure. The terms “including” and “having” and any variations thereof in the specification, claims, and drawings are intended to cover non-exclusive inclusion.

In the description of the embodiments of the present disclosure, the technical terms “first”, “second”, etc. are intended only to distinguish different objects and are not to be understood as indicating or implying a relative importance or as implicitly indicating a number, specific sequence, or priority of the technical features indicated. In the description of the embodiments of the present disclosure, the meaning of “multiple” is two or more, unless otherwise specifically qualified.

References to “an embodiment” mean that the particular feature, structure, or characteristic described in connection with the embodiment may be included in at least one embodiment of the present disclosure. This phrase does not necessarily refer to the same embodiment at each location in the description, nor does it refer to mutually exclusive or alternative embodiments. It is understood, explicitly and implicitly, by those skilled in the art that the embodiments described herein may be combined with other embodiments.

In the description of the embodiments of the present disclosure, the term “and/or” is intended to describe the relationship between related objects, indicating that there may be three relationships, for example, A and/or B, which may indicate the following three situations: A alone, A and B at the same time, and B alone. In addition, the character “/” generally indicates that the related objects before and after are in an “or” relationship.

In the description of the present disclosure, the term “multiple” refers to two or more (including two), and similarly, “multiple groups” refers to two or more groups (including two groups), and “multiple pieces” refers to two or more pieces (including two pieces).

In the description of the embodiments of the present disclosure, the technical terms “center”, “longitudinal”, “transverse”, “length”, “width”, “thickness”, “upper”, “lower”, “front”, “rear”, “left”, “right”, “vertical”, “horizontal”, “top”, “bottom”, “inner”, “outer”, “clockwise”, “counterclockwise”, “axial”, “radial”, “peripheral” and other indications of orientation or position relationship are based on the orientation or position relationship shown in the drawings, and are only for the convenience of describing the embodiments of the present disclosure and simplifying the description, but are not intended to indicate or imply that the device or element referred to must have a specific orientation or be constructed and operated in a specific orientation, and therefore cannot be understood as a limitation of the embodiments of the present disclosure.

In the description of the embodiments of the present disclosure, unless otherwise expressly provided and limited, the technical terms “mounted”, “connected”, “attached”, “fixed”, etc. shall be understood in a broad sense. For example, they may be fixed connections, removable connections, or integral; they may be mechanical connections or electrical connections; they may be directly connected or indirectly connected through an intermediate medium; they may be internal connections between two components or interactions between two components. Those skilled in the art can understand the specific meaning of the above terms in the embodiments of the present disclosure according to the specific circumstances.

With the continuous development of display technology, organic light-emitting diode (OLED) has become a research hotspot and the direction of technological development for major manufacturers due to its advantages of wide color gamut, high contrast, thin and light design, self-luminous, and wide viewing angle, etc.

Nowadays, in order to meet user needs, some OLED display devices are required to have high light transmittance in a local functional region while displaying images normally, that is, a light-transmitting region is required to be arranged in the screen region above the light-sensing device (mainly the region of an under-screen camera). However, in existing display panels, the non-light-transmitting regions between the light-transmitting regions are not fully utilized, resulting in poor functional characteristics of the display panels.

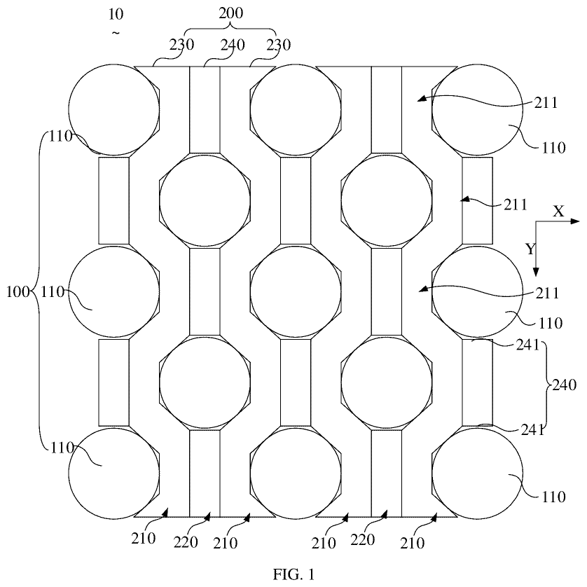

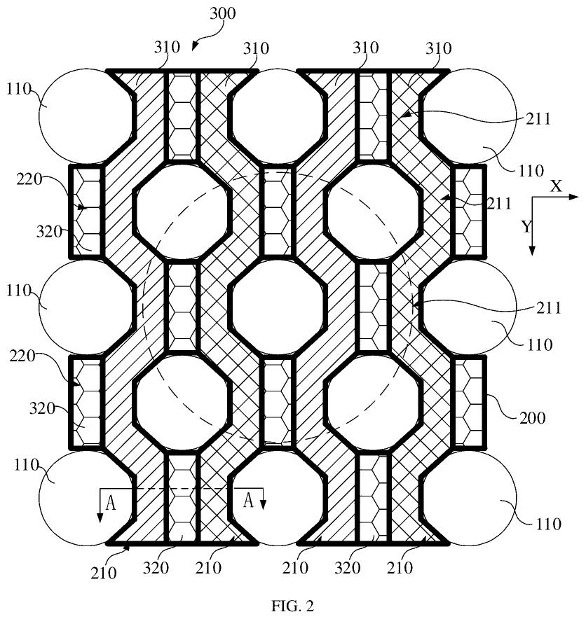

To solve the technical problems in the related art, the present disclosure provides a display panel. Referring to FIGS. 1 and 2, FIG. 1 is a first schematic structural view of a display panel according to some embodiments of the present disclosure, and FIG. 2 is a second schematic structural view of a display panel according to some embodiments of the present disclosure.

The display panel 10 includes multiple light-transmitting region columns 100, a conductive barrier structure 200, and a pixel unit group 300. The multiple light-transmitting region columns 100 are arranged side by side and spaced apart in a first direction X, and each light-transmitting region column 100 includes multiple light-transmitting sub-regions 110 spaced apart in a second direction Y. The light-transmitting sub-regions 110 of two adjacent light-transmitting region columns 100 are misaligned in the first direction X, where the first direction X is perpendicular to the second direction Y. The conductive barrier structure 200 surrounds to form multiple first pixel holding regions 210 and multiple second pixel holding regions 220. The first pixel holding regions 210 and the light-transmitting region columns 100 are arranged side by side and staggered in the first direction X, that is, they are distributed in the first direction X as: light-transmitting region columns 100, first pixel holding region 210, light-transmitting region columns 100, first pixel holding region 210, etc. Each first pixel holding region 210 includes multiple sub-holding regions 211 connected to each other along the second direction Y, and each sub-holding region 211 faces a corresponding light-transmitting sub-region 110. Each second pixel holding region 220 is disposed at an interval between corresponding adjacent two light-transmitting sub-regions 110 of a corresponding light-transmitting region column 100. The pixel unit group 300 includes multiple pixel columns 310 and first pixel units 320. The multiple pixel columns 310 are arranged in the first pixel holding regions 210 in a one-to-one correspondence, and each pixel column 310 extends along an extension direction of its corresponding first pixel holding region 210. The multiple first pixel units 320 are arranged in the second pixel holding regions 220 in a one-to-one correspondence.

Each light-transmitting region column 100 may include multiple light-transmitting sub-regions 110. For example, the display panel 10 shown in FIGS. 1 and 2 includes five light-transmitting region columns 100, where the first, third, and fifth light-transmitting region columns 100 each include three light-transmitting sub-regions 110 spaced apart in the second direction Y, and the second and fourth light-transmitting region columns 100 each include two light-transmitting sub-regions 110 spaced apart in the second direction Y. The light-transmitting sub-regions 110 of adjacent columns are misaligned in the first direction X, i.e., there are no two light-transmitting sub-regions 110 in the same straight line between adjacent columns in the first direction X, such that there is a non-light-transmitting region around each light-transmitting sub-region 110. The non-light-transmitting region can be configured to arrange a pixel, which may include red, green and blue pixels, etc., such that the light-transmitting sub-regions 110 can serve as a camera region and further for display purposes. The shape of each light-transmitting sub-region 110 may include, but is not limited to, a circle, triangle, quadrilateral, or other polygon.

In the embodiments, the multiple first pixel holding regions 210 and multiple second pixel holding regions 220 are formed by a conductive barrier structure 200, the pixel columns 310 are arranged in the first pixel holding regions 210 in a one-to-one correspondence, and the first pixel units 320 are arranged in the second pixel holding regions 220 in a one-to-one correspondence, such that the organic light-emitting material can be distilled by using the conductive barrier structure 200 to replace the process of depositing the organic light-emitting material by using a fine metal mask (FMM) in the traditional technology. Therefore, the shape of the pixel column 310 in the present disclosure can be set independently without being limited by the shape of the mask. Taking the display panel 10 shown in FIGS. 1 and 2 as an example, it includes four first pixel holding regions 210 and twelve second pixel holding regions 220. Each first pixel holding region 210 is disposed between two light-transmitting region columns 100 in the first direction X. Each second pixel holding region 220 is disposed between corresponding two light-transmitting sub-regions 110. Each first pixel holding region 210 includes multiple sub-holding region 211, one sub-holding region 211 corresponding to one light-transmitting sub-region 110. The sub-holding region 211 may be annular, convex, or linear, etc. Taking the sub-holding region 211 being annular as an example, each light-transmitting sub-region 110 is located on a concave side of its corresponding sub-holding region 211, such that the sub-holding region 211 can surround a portion of the light-transmitting sub-region 110. The first pixel holding regions 210 on both sides of one light-transmitting region column 100 are arranged symmetrically, such that the sub-holding regions 211 on both sides of the light-transmitting sub-region 110 surround the light-transmitting sub-region 110, thereby forming a surrounding structure for the light-transmitting sub-region 110 to make full use of the non-light-transmitting region to arrange the first pixel holding regions 210. When the pixel columns 310 are arranged in correspondence with the first pixel holding regions 210 and the first pixel units 320 are arranged in correspondence with the second pixel holding regions 220, the pixel arrangement area of the display panel 10 and the pixel opening ratio can be further increased compared to the arrangement of pixel holding regions only between two light-transmitting sub-regions 110 in the same row or column.

In the above embodiments, the first pixel holding regions 210 and the light-transmitting region columns 100 are arranged side by side and staggered in the first direction X, and there is a second pixel holding region 220 in the interval between two adjacent light-transmitting sub-regions 110 of each light-transmitting region column 100, such that the first pixel holding regions 210 and the second pixel holding regions 220 occupy as much as possible the non-light-transmitting region between the light-transmitting sub-regions 110. When the pixel column 310 is arranged in the first pixel holding region 210 and the first pixel unit 320 is arranged in the second pixel holding region 220, the pixel column 310 and the first pixel unit 320 can be arranged in the gap between the light-transmitting sub-regions 110, making full use of the non-light-transmitting region between the light-transmitting regions, thereby increasing the pixel arrangement area of the display panel 10 and increasing the pixel opening ratio, etc.

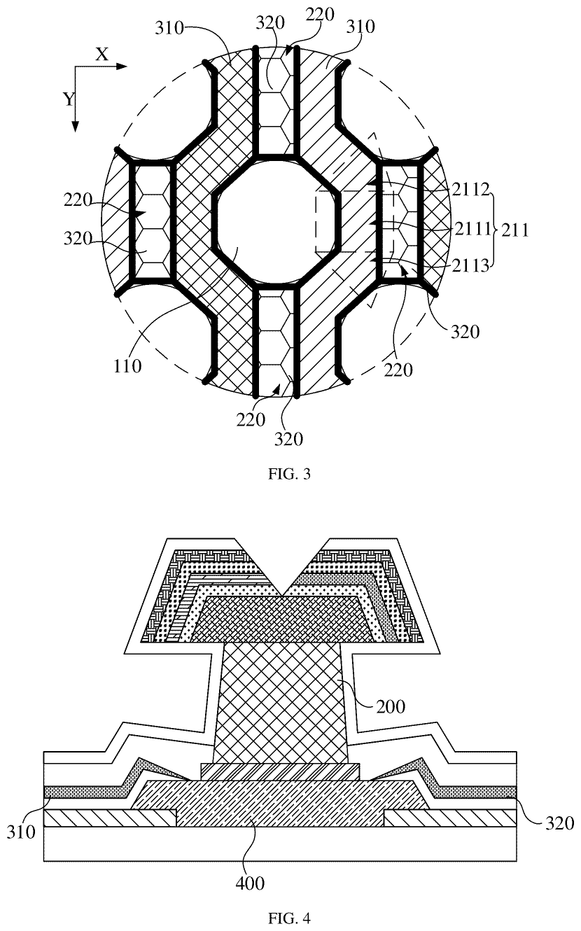

FIG. 3 is an enlarged schematic view of the structure within the broken-line frame in FIG. 2.

The sub-holding region 211 includes a first holding segment 2111, a second holding segment 2112, and a third holding segment 2113. The first holding segment 2111 is connected to the second holding segment 2112 and the third holding segment 2113; the first holding segment 2111 extends in the second direction Y; the second holding segment 2112 and the third holding segment 2113 are respectively extended in a direction inclined to the second direction Y; the first holding segment 2111 of one sub-holding region 211 is connected to the third holding segment 2113 of another sub-holding region 211. The first holding segment 2111 extends in the second direction Y; the second holding segment 2112 and the third holding segment 2113 are connected to both sides of the first holding segment 2111 in the second direction Y, respectively, and the second holding segment 2112 and the third holding segment 2113 are respectively extended in a direction inclined to the second direction Y. For example, in the sub-holding region 211 in the broken-line frame in FIG. 3, the second holding segment 2112 is extended to the left and up relative to the first holding segment 2111, and the third holding segment 2113 is extended to the left and down relative to the first holding segment 2111, thereby forming the sub-holding region 211. Further, the sub-holding region 211 formed by the connection of the three holding segments is easier to manufacture, and it is easier to surround the outer periphery of the light-transmitting sub-region 110, making better use of the non-light-transmitting region between the light-transmitting regions, thereby further increasing the pixel arrangement area of the display panel 10 and increasing the pixel opening ratio, etc.

Furthermore, the light-transmitting sub-region 110 is circular, and one light-transmitting sub-region 110 is surrounded by two corresponding sub-holding regions 211 and two adjacent second pixel holding regions 220. The two sub-holding regions 211 and the two second pixel holding regions 220 surround the light-transmitting sub-region 110, and when the light-transmitting sub-region 110 is circular, the pixels can occupy more space in the non-light-transmitting region through reasonable arrangement of the pixels, thereby further increasing the pixel arrangement area of the display panel 10 and increasing the pixel opening ratio, etc.

In some embodiments, when the sub-holding region 211 is annular, the protruding directions of the two adjacent sub-holding regions 211 are opposite, and the light-transmitting sub-holding region 110 is located on the concave side of its corresponding sub-holding region 211, the second pixel holding region 220 may be located at an interval in the first direction X between the first holding segment 2111 of one first pixel holding region 210 and the first holding segment 2111 of another adjacent first pixel holding region 210.

The second pixel holding regions 220 may be arranged in a strip shape, and each second pixel holding region 220 may extend in the second direction Y. Each second pixel holding region 220 may be arranged between two light-transmitting sub-regions 110, for example, the second pixel holding regions 220 of the same column may be arranged in one light-transmitting region column 100. For example, referring to FIGS. 1 and 2, the display panel 10 includes a total of 12 second pixel holding regions 220, which are divided into five columns. From left to right, the two second pixel holding regions 220 in the first column are arranged in a same column with the three light-transmitting sub-regions 110 of the light-transmitting region column 100 in the first column; the three second pixel holding regions 220 in the second column are arranged in a same column with the two light-transmitting sub-regions 110 of the light-transmitting region column 100 in the second column; the two second pixel holding regions 220 in the third column are arranged in a same column with the three light-transmitting sub-regions 110 of the light-transmitting region column 100 in the third column; the three second pixel holding regions 220 in the fourth column are arranged in a same column with the two light-transmitting sub-regions 110 of the light-transmitting region column 100 in the fourth column; the two second pixel holding regions 220 in the fifth column are arranged in a same column with the three light-transmitting sub-regions 110 of the light-transmitting region column 100 in the fifth column. Each first pixel unit 320 is accommodated in a corresponding second pixel holding region 220, and the second pixel holding region 220 is formed by a corresponding first holding segment 2111 being spaced with another adjacent in the first direction X, which facilitates separation of the first pixel unit 320 from the adjacent pixel column 310 by the conductive barrier structure 200.

Further, the conductive barrier structure 200 includes at least one first barrier structure 230 and multiple second barrier structures 240, where each first barrier structure 230 is configured to form a corresponding first pixel holding region 210. Each second barrier structure 240 includes two barrier walls 241 spaced apart in the second direction Y, and each of the two barrier walls 241 is connected to a portion of the first barrier structure 230 to form the first pixel holding region 2111, so as to form the second pixel holding region 220.

The number of the first barrier structures 230 may be more than one, and each first barrier structure 230 may be configured to form a corresponding first pixel holding region 210. The multiple first barrier structures 230 may be arranged at intervals in the first direction X. The second barrier structure 240 may be configured to form multiple second pixel holding regions 220 in conjunction with the first barrier structures 230. Specifically, each second barrier structure 240 is located between a corresponding first holding segment 2111 and another opposite first holding segment 2111. Each second barrier structure 240 includes two barrier walls 241, each of which is connected to two adjacent first barrier structures 230, and the two barrier walls 241 are spaced apart in the second direction Y. In this way, one second barrier structure 240 and corresponding two adjacent first barrier structures 230 cooperate to form a corresponding second pixel holding region 220, and the first pixel holding region 210 and the second pixel holding region 220 can share portions of the barrier structures, which may reduce the space occupied by the barrier structures, so as to facilitate the arrangement of more pixels in the non-light-transmitting region, and further increase the pixel opening area of the display panel 10.

In some embodiments, the first pixel unit 320 is a green pixel, and in the first direction X, the first pixel units 320 located on both sides of one light-transmitting sub-region 110 are symmetrically arranged with respect to the light-transmitting sub-region 110; and/or, in the second direction Y, the first pixel units 320 located on both sides of one light-transmitting sub-region 110 are symmetrically arranged with respect to the light-transmitting sub-region 110.

The first pixel unit 320 is located in a corresponding second pixel holding region 220, and in the first direction X, two adjacent first pixel holding regions 210 are symmetrically arranged along the light-transmitting region column 100 in between. The first holding segment 2111 of one first pixel holding region 210 is spaced apart with the first holding segment 2111 of another adjacent first pixel holding region 210 in the first direction X to form multiple second pixel holding regions 220. In this way, in the first direction X, the first pixel units 320 located on both sides of one light-transmitting sub-region 110 are arranged symmetrically with respect to the light-transmitting sub-region 110, and in the second direction Y, the first pixel units 320 located on both sides of one light-transmitting sub-region 110 are arranged symmetrically with respect to the light-transmitting sub-region 110. For example, in the display panel 10 shown in FIG. 2, the light-transmitting sub-region 110 in the center of the broken-line frame is taken as an example. Among the four first pixel units 320 arranged around the light-transmitting sub-region 110, the upper and lower first pixel units 320 can be arranged symmetrically along the light-transmitting sub-region 110, and the left and right first pixel units 320 can also be arranged symmetrically along the light-transmitting sub-region 110. The first pixel units 320 are each a green pixel, and they are evenly distributed around the light-transmitting sub-region 110, which makes the brightness of the display more uniform.

Furthermore, in the first direction X, one of two adjacent pixel columns 310 is a blue pixel column 310 and the other is a red pixel column 310. That is, in each two adjacent pixel columns 310 arranged in the first direction X, one is a blue pixel column 310, and the other is a red pixel column 310. The first pixel units 320 between the two pixel columns 310 are a green pixel column, which makes the arrangement of the pixel units 300 more reasonable, thereby making the brightness of the display more uniform. For example, in the display panel 10 shown in FIG. 2, the first, third, and fifth pixel columns 310 from left to right may be red pixel columns 310, and the second and fourth pixel columns 310 may be blue pixel column 310; or the first, third, and fifth pixel columns 310 may be blue pixel columns 310, and the second and fourth pixel column 310 may be red pixel columns 310.

The conductive barrier structure 200 may be configured to separate the pixel columns 310 and the first pixel units 320. Specifically, referring to FIG. 4, FIG. 4 is a partial cross-sectional structural view of the display panel 10 shown in FIG. 2 along the A-A direction.

As shown in FIG. 4, the pixel column 310 and the first pixel unit 320 are separated by the conductive barrier structure 200. Specifically, a pixel definition layer 400 is arranged on a drive substrate of the display panel 10, and the pixel definition layer 400 protrudes from the drive substrate to define a pixel holding region. The conductive barrier structure 200 is disposed on a side of the pixel definition layer 400 that is away from the drive substrate, and the pixel holding region is divided into the first pixel holding region 210 and the second pixel holding region 220 by the conductive barrier structure 200. The pixel column 310 is disposed in the first pixel holding region 210, and the first pixel unit 320 is disposed in the second pixel holding region 220. The pixel column 310 and the first pixel unit 320 are separated by the conductive barrier structure 200, such that the organic light-emitting material can be distilled by using the conductive barrier structure 200 to replace the process of depositing the organic light-emitting material by using a fine metal mask (FMM) in the traditional technology.

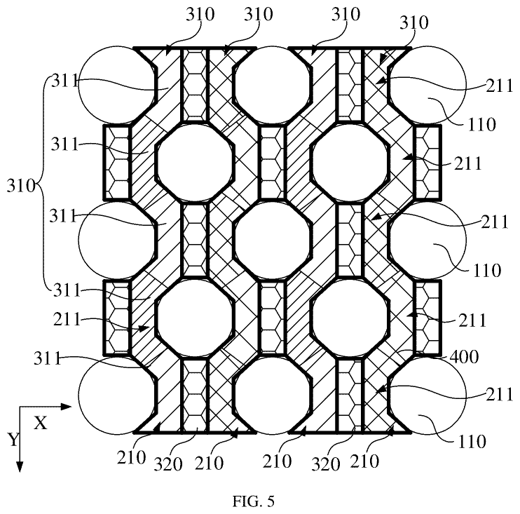

Referring to FIG. 5, FIG. 5 is a third schematic structural view of a display panel 10 according to some embodiments of the present disclosure.

The pixel column 310 includes multiple second pixel units 311, where each second pixel unit 311 is disposed in a corresponding sub-holding region 211, and each two adjacent second pixel units 311 are separated by the pixel definition layer 400. The pixel definition layer 400 can be understood as a PDL film. For example, in the display panel 10 shown in FIG. 5, each pixel column 310 includes five sub-holding regions 211, each of which may be configured to accommodate a corresponding second pixel unit 311, and each adjacent two second pixel units 311 are separated by the pixel definition layer 400, which is more conducive to improving the utilization rate of the openings than a design where the conductive barrier structure 200 separates each adjacent two second pixel units 311. The colors of multiple second pixel units 311 in the same pixel column 310 may be the same, for example, multiple second pixel units 311 in the same pixel column 310 may be all red pixels, all blue pixels, or all green pixels, etc. Alternatively, the colors of multiple second pixel units 311 in the same pixel column 310 may be different, for example, multiple second pixel units 311 in the same pixel column 310 may include at least one of red pixels, blue pixels, or green pixels, etc.

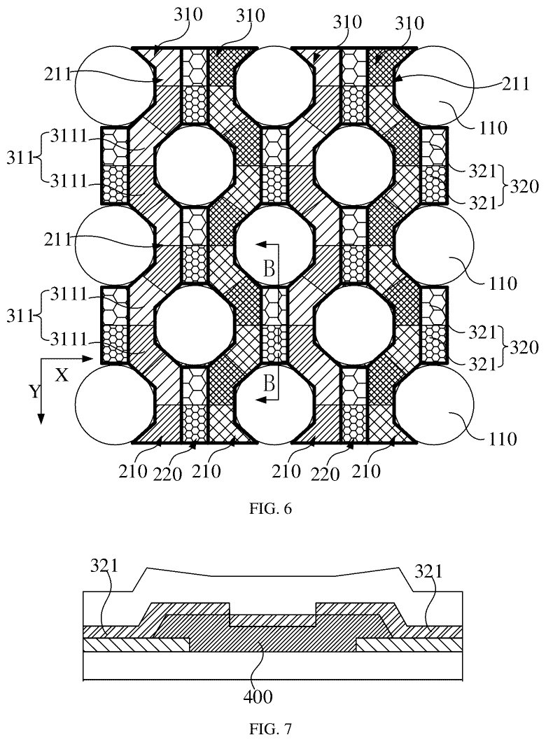

Referring to FIG. 6, FIG. 6 is a fourth schematic structural view of a display panel 10 according to some embodiments of the present disclosure.

The second pixel unit 311 includes at least two second subpixels 3111 arranged in an extension direction, and each adjacent two second subpixels 3111 are spaced apart by the pixel definition layer 400. Each sub-holding region 211 accommodates a corresponding second pixel unit 311, and in the embodiments, each second pixel unit 311 may further include at least two second subpixels 3111, with the at least two second subpixels 3111 spaced apart by the pixel definition layer 400. That is, a greater number of pixels can be accommodated within the same sub-holding region 211, thereby increasing the resolution. In particular, the colors of the multiple second subpixels 3111 in the same pixel column 310 may be the same, for example, the multiple second subpixels 3111 in the same pixel column 310 may be red pixels, blue pixels, or green pixels, etc. Alternatively, the colors of multiple second subpixels 3111 in the same pixel column 310 may not be the same, for example, the multiple second subpixels 3111 in the same pixel column 310 may include at least one of red, blue or green pixels, etc. The pixel definition layer 400 may be understood as a PDL film, and the second subpixel 3111 is separated from the adjacent second subpixel 3111 by the pixel definition layer 400, which may improve the utilization rate of the openings relative to a design where the conductive barrier structure 200 separates each adjacent second subpixels 3111.

In some embodiments, the first pixel unit 320 includes at least two first subpixels 321 arranged in an extension direction, and each adjacent two first subpixels 321 are spaced apart by the pixel definition layer 400. Each second pixel holding region 220 accommodates a corresponding first pixel unit 320, each first pixel unit 320 includes at least two second subpixels 3111, and at least two first subpixels 321 are spaced apart by the pixel definition layer 400, that is, within the same second holding region 2112, a greater number of first subpixels 321 can be accommodated, thereby increasing the resolution. The colors of multiple first subpixels 321 of the same first pixel unit 320 may be the same, for example, multiple first subpixels 321 of the same first pixel unit 320 may be red pixels, blue pixels or green pixels, etc. Alternatively, the colors of multiple first subpixels 321 of the same first pixel unit 320 may be different, for example, multiple first subpixels 321 of the same first pixel unit 320 may include at least one of red, blue or green pixels, etc. The pixel definition layer 400 may be understood as a PDL film, and the two adjacent first subpixels 321 are separated by the pixel definition layer 400, which may improve the utilization rate of the openings relative to a design where each two adjacent first subpixels 321 are separated by the conductive barrier structure 200.

Specifically, referring to FIG. 7, FIG. 7 is a partial cross-sectional structural view of the display panel 10 shown in FIG. 6 along the B-B direction.

Two first subpixels 321 may be separated by the pixel definition layer 400. Specifically, a pixel definition layer 400 may be arranged on the drive substrate of the display panel 10, and the pixel definition layer 400 protrudes from the drive substrate to define a pixel holding region. The two first subpixels 321 are located in the pixel holding region on both sides of the pixel definition layer 400, such that the two first subpixels 321 are separated by the pixel definition layer 400, which may improve the utilization of the openings compared to a design where the two first subpixels 321 are separated by the conductive barrier structure 200. In particular, the structure in which two second pixel units 311 are spaced apart by the pixel definition layer 400, and the structure in which two second subpixels 3111 are spaced apart by the pixel definition layer 400, may be the same or similar to the structure in which two first subpixels 321 are spaced apart by the pixel definition layer 400, which will not be described in detail.

In summary, the first pixel holding region 210 and the light-transmitting region column 100 are arranged side by side and staggered in the first direction X, and there is a second pixel holding region 220 in the interval between two adjacent light-transmitting sub-regions 110 of each light-transmitting region column 100, such that the first pixel holding region 210 and the second pixel holding region 220 occupy as much as possible the non-light-transmitting region between the light-transmitting sub-regions 110. When the pixel column 310 is arranged in the first pixel holding region 210 and the first pixel unit 320 is arranged in the second pixel holding region 220, the pixel column 310 and the first pixel unit 320 can be arranged in the gap between the light-transmitting sub-regions 110, making full use of the non-light-transmitting region between the light-transmitting regions, thereby increasing the pixel arrangement area of the display panel 10 and increasing the pixel opening ratio, etc.

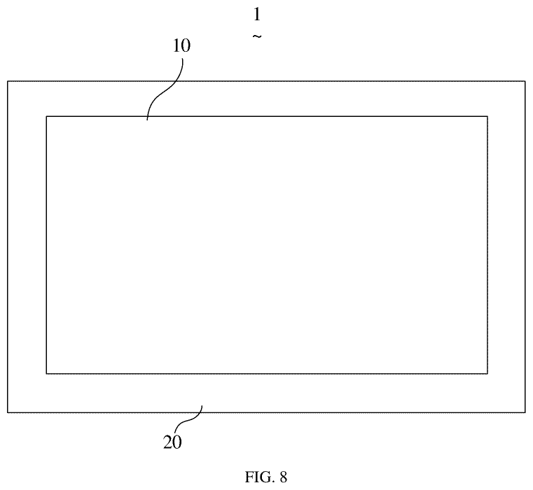

In order to solve the technical problems in the related art, the present disclosure further provides an electronic device 1. Referring to FIG. 8, FIG. 8 is a schematic structural view of an electronic device 1 according to some embodiments of the present disclosure.

The electronic device 1 includes a housing 20 and a display panel 10 of any of the above embodiments, and the housing 20 is configured to support the display panel 10. It should be noted that the electronic device 1 in the embodiments of the present disclosure may be a TV, mobile phone, smart phone, tablet computer, notebook computer, etc. Specifically, the display device may be an under-screen camera device, which may include a camera module that overlaps at least partially with a portion of the display panel 10 having the light-transmitting region column 100. The camera module includes a camera, which may be a front camera. When the camera is used, a region of the display panel 10 having the light-transmitting region column 100 is not displayed, such that the camera can perform the image capturing function. When the camera is not used, the region of the display panel 10 having the light-transmitting region column 100 can display images.

Finally, it should be noted that the above embodiments are only intended to illustrate the technical solution of the present disclosure, not to limit the same. Although the present disclosure is described in detail with reference to the above embodiments, those skilled in the art should understand that the technical solution described in the above embodiments can still be modified, or some or all of the technical features can be replaced by equivalent ones. In particular, the various technical features mentioned in the various embodiments can be combined in any way as long as there is no structural conflict. The present disclosure is not limited to the specific embodiments disclosed herein, but includes all technical solutions that fall within the scope of the claims.

What is claimed is:

1. A display panel, comprising:
a plurality of light-transmitting region columns, arranged side by side and spaced apart in a first direction; wherein each light-transmitting region column comprises a plurality of light-transmitting sub-regions spaced apart in a second direction; the plurality of light-transmitting sub-regions of each adjacent two of the plurality of light-transmitting region columns are misaligned in the first direction, where the first direction is perpendicular to the second direction;
a conductive barrier structure, surrounding to form a plurality of first pixel holding regions and a plurality of second pixel holding regions; wherein the plurality of first pixel holding regions and the plurality of light-transmitting region columns are arranged side by side and staggered in the first direction; each first pixel holding region comprises a plurality of sub-holding regions connected to each other along the second direction, and each sub-holding region faces a corresponding light-transmitting sub-region; each second pixel holding region is disposed in an interval between corresponding adjacent two of the plurality of light-transmitting sub-regions of a corresponding light-transmitting region column; and
a pixel unit group, comprising a plurality of pixel columns and a plurality of first pixel units; wherein the plurality of pixel columns are arranged in the plurality of first pixel holding regions in a one-to-one correspondence, and each pixel column extends along an extension direction of a corresponding first pixel holding region; the plurality of first pixel units are arranged in the plurality of second pixel holding regions in a one-to-one correspondence.

2. The display panel according to claim 1, wherein each sub-holding region comprises a first holding segment, a second holding segment, and a third holding segment; the first holding segment is connected to the second holding segment and the third holding segment; the first holding segment extends in the second direction; the second holding segment and the third holding segment are each extended in a direction inclined to the second direction;
the first holding segment of one of the plurality of sub-holding regions is connected to the third holding segment of another of the plurality of sub-holding regions.

3. The display panel according to claim 2, wherein the conductive barrier structure comprises at least one first barrier structure and a plurality of second barrier structures; each first barrier structure is configured to form a corresponding first pixel holding region; each second barrier structure comprises two barrier walls spaced apart in the second direction, and each of the two barrier walls is connected to a portion of the at least one first barrier structure to form a corresponding first pixel holding region, so as to form a corresponding second pixel holding region.

4. The display panel according to claim 1, wherein each first pixel unit is a green pixel; two of the plurality of first pixel units located on both sides of each light-transmitting sub-region in the first direction are symmetrically arranged with respect to the light-transmitting sub-region; and/or, two of the plurality of first pixel units located on both sides of each light-transmitting sub-region in the second direction are symmetrically arranged with respect to the light-transmitting sub-region.

5. The display panel according to claim 4, wherein in the first direction, one of each adjacent two of the plurality of pixel columns is a blue pixel column and the other is a red pixel column.

6. The display panel according to claim 1, wherein each first pixel unit comprises at least two first subpixels arranged in an extension direction of the first pixel unit, and each adjacent two of the at least two first subpixels are spaced apart by a pixel definition layer.

7. The display panel according to claim 2, wherein each pixel column comprises a plurality of second pixel units; each second pixel unit is disposed in a corresponding sub-holding region, and each adjacent two of the plurality of second pixel units are separated by a pixel definition layer.

8. The display panel according to claim 7, wherein each second pixel unit comprises at least two second subpixels arranged in an extension direction of the second pixel unit, and each adjacent two of the at least two second subpixels are spaced apart by the pixel definition layer.

9. The display panel according to claim 1, wherein each light-transmitting sub-region is circular;
each light-transmitting sub-region is surrounded by two corresponding sub-holding regions and two corresponding adjacent second pixel holding regions.

10. The display panel according to claim 1, wherein each sub-holding region is annular, and each light-transmitting sub-region is located on a concave side of a corresponding sub-holding region.

11. The display panel according to claim 1, wherein a pixel definition layer is arranged on a drive substrate of the display panel, and the pixel definition layer protrudes from the drive substrate to define a pixel holding region; the conductive barrier structure is disposed on a side of the pixel definition layer that is away from the drive substrate, and the pixel holding region is divided into the first pixel holding region and the second pixel holding region by the conductive barrier structure.

12. An electronic device, comprising a housing and a display panel;
wherein the display panel comprises:
a plurality of light-transmitting region columns, arranged side by side and spaced apart in a first direction; wherein each light-transmitting region column comprises a plurality of light-transmitting sub-regions spaced apart in a second direction; the plurality of light-transmitting sub-regions of each adjacent two of the plurality of light-transmitting region columns are misaligned in the first direction, where the first direction is perpendicular to the second direction;
a conductive barrier structure, surrounding to form a plurality of first pixel holding regions and a plurality of second pixel holding regions; wherein the plurality of first pixel holding regions and the plurality of light-transmitting region columns are arranged side by side and staggered in the first direction; each first pixel holding region comprises a plurality of sub-holding regions connected to each other along the second direction, and each sub-holding region faces a corresponding light-transmitting sub-region; each second pixel holding region is disposed in an interval between corresponding adjacent two of the plurality of light-transmitting sub-regions of a corresponding light-transmitting region column; and
a pixel unit group, comprising a plurality of pixel columns and a plurality of first pixel units; wherein the plurality of pixel columns are arranged in the plurality of first pixel holding regions in a one-to-one correspondence, and each pixel column extends along an extension direction of a corresponding first pixel holding region; the plurality of first pixel units are arranged in the plurality of second pixel holding regions in a one-to-one correspondence.

13. The electronic device according to claim 12, wherein each sub-holding region comprises a first holding segment, a second holding segment, and a third holding segment; the first holding segment is connected to the second holding segment and the third holding segment; the first holding segment extends in the second direction; the second holding segment and the third holding segment are each extended in a direction inclined to the second direction;
the first holding segment of one of the plurality of sub-holding regions is connected to the third holding segment of another of the plurality of sub-holding regions.

14. The electronic device according to claim 13, wherein the conductive barrier structure comprises at least one first barrier structure and a plurality of second barrier structures; each first barrier structure is configured to form a corresponding first pixel holding region; each second barrier structure comprises two barrier walls spaced apart in the second direction, and each of the two barrier walls is connected to a portion of the at least one first barrier structure to form a corresponding first pixel holding region, so as to form a corresponding second pixel holding region.

15. The electronic device according to claim 12, wherein each first pixel unit is a green pixel; two of the plurality of first pixel units located on both sides of each light-transmitting sub-region in the first direction are symmetrically arranged with respect to the light-transmitting sub-region; and/or, two of the plurality of first pixel units located on both sides of each light-transmitting sub-region in the second direction are symmetrically arranged with respect to the light-transmitting sub-region.

16. The electronic device according to claim 15, wherein in the first direction, one of each adjacent two of the plurality of pixel columns is a blue pixel column and the other is a red pixel column.

17. The electronic device according to claim 12, wherein each first pixel unit comprises at least two first subpixels arranged in an extension direction of the first pixel unit, and each adjacent two of the at least two first subpixels are spaced apart by a pixel definition layer.

18. The electronic device according to claim 13, wherein each pixel column comprises a plurality of second pixel units; each second pixel unit is disposed in a corresponding sub-holding region, and each adjacent two of the plurality of second pixel units are separated by a pixel definition layer.

19. The electronic device according to claim 18, wherein each second pixel unit comprises at least two second subpixels arranged in an extension direction of the second pixel unit, and each adjacent two of the at least two second subpixels are spaced apart by the pixel definition layer.

20. The electronic device according to claim 12, wherein each light-transmitting sub-region is circular;
each light-transmitting sub-region is surrounded by two corresponding sub-holding regions and two corresponding adjacent second pixel holding regions.
